(19) United States
(12) Patent Application Publication
(10) Pub. No.: US 2026/0262336 A1
(43) Pub. Date: Sep. 3, 2026

(54) METHOD FOR PROCESSING A PLURALITY OF OPTOELECTRONIC DEVICES AND OPTOELECTRONIC DEVICE

(71) Applicant: ams-OSRAM International GmbH, Regensburg (DE)

(72) Inventor: Tansen Varghese, Regensburg (DE)

(21) Appl. No.: 18/994,470

(22) PCT Filed: Jul. 19, 2023
(86) PCT No.: PCT/EP2023/070036

§ 371 Date: Jan. 14, 2025

(30) Foreign Application Priority Data
Jul. 19, 2022 (DE) 10 2022 118 081.6

(51) Int. Cl. H10H 20/815; H10H 20/01; H10H 20/819; H10H 20/824; H10H 20/84

(52) U.S. Cl. CPC H10H 20/815; H10H 20/0133; H10H 20/017; H10H 20/034; H10H 20/819; H10H 20/824; H10H 20/84

(57) ABSTRACT

In an embodiment a method includes providing a Si substrate having a {100} surface-oriented plane and having a dielectric layer arranged thereupon, providing a recess on the surface of the dielectric layer and extending into the Si substrate, whereas the recess comprises a oriented sidewall on at least two opposing sides in the Si substrate, growing a plug layer in the recess, wherein the plug layer comprises a III-V semiconductor material up to and above the surface of the dielectric layer, growing a buffer layer of a III-V semiconductor material on the plug layer, the plug or buffer layer being at least partially grown with an inclined sidewall having an increasing cross-section with increasing distance from the dielectric layer, growing a layer stack on the buffer layer, the layer stack comprising an embedded active layer and being separated from each other, wherein the embedded active layer is spatially distant from sidewalls of the layer stack, applying a dielectric material on the sidewalls of the layer stack; and applying a contact area on a top surface of the layer stack.

### CROSS-REFERENCE TO RELATED APPLICATIONS

This patent application is a national phase filing under section 371 of PCT/EP 2023/070036, filed Jul. 19, 2023, which claims the priority of German patent application no. 102022118081.6, filed Jul. 19, 2022, each of which is incorporated herein by reference in its entirety.

### TECHNICAL FIELD

The present invention concerns a method for processing a plurality of optoelectronic devices. The present invention also concerns an optoelectronic device.

### BACKGROUND

Very small LEDs also referred to as μ-LEDs are currently implemented in many different applications ranging from pixelated displays such as in AR/VR to head lamps.

However, due to the small size, μ-LEDs often suffer from efficiency losses due to non-radiative recombination (NRR) at the edges of their active region. The reason for the degradation is two-fold. For one, conventional processing techniques usually require a mesa etching step resulting in an etching through the active region in order to isolate the respective pixels electrically and optically. The etching process causes dangling bonds at the edge of the active region that act as non-radiative recombination centres. Although, this aspect may generally occur in LEDs no matter its size, the small size of μ-LEDs worsens this issue due to the reduced aspect ratio (area/circumference).

To counter this issue, several different methods have been employed including for example passivating the edges of the layer stack and in particular the active region. This approach is based on the respective material system using for instance ALD deposition. In addition, one may use quantum well intermixing for certain material systems. Other options are pre-passivating etches and cleans. Still, many of these approaches have resulted in an unsatisfying improvement of the internal quantum efficiency (IQE).

Another issue concerns the further processing of the optoelectronic devices. Apart from various wafer transfer processes, the final carrier is usually based on Si and employs various CMOS circuitry to control and supply the u-LEDs placed on its surface. It has been proposed to grow III-V devices directly on an Si substrate to enable a good wafer to wafer bonding and avoid run-out and bow problems caused by CTE mismatch. As an alternative, one could process the III-V devices on already pre-fabricated CMOS wafers. However, III-V-based u-LED processing on Si faces some challenges due to lattice mismatch and CTE mismatch challenges. It has been found that GaN based devices can be grown on Si with only a slight loss of IQE. Different methods of growing or transferring GaAs-based u-LEDs onto Si have been pursued, with varying levels of success when it comes to mitigating the issues of lattice mismatch and CTE mismatch.

### SUMMARY

Embodiments provide to utilize aspect ratio trapping (ART) by etching recesses into an Si carrier and then growing III-V material in these recesses, confined by additional dielectric on the sides above the recess in the Si. The recesses are confined both in x- and y-directions resulting in a hole of a certain depth and cross-section. Such holes will not extend in any of those directions past a few hundred nm. More particularly, the etch in the Si substrate is performed onto a {100} plane, along <110> directions, thereby leaving inclined {111} planes as the sidewalls of the recess. These inclined {111} planes significantly reduce any phase disorder in a plug of III-V material grown therein.

The wet etched shape in Si can be used to prevent different defects from arising. For example, trenches with sidewalls along the {111} planes prevent planar defects such as antiphase boundaries (APBs) in GaAs grown on Si. Deposition of III-V material like GaN or GaAs is carried out to form a plug, for example, with growth nucleating only on the etched recess Si {111} planes. The steep aspect ratio (depth/width) of the etched recesses prevents defects such as dislocations and planar defects from propagating out into the active region. Growth conditions tailored to form defects only parallel to the {111} planes and using a dielectric to prevent these defects from coming out of the recess in the Si is another way of preventing defects at the active region level of devices grown on top of these plugs.

The use of a GaAs plug allows for further processing additional layers based on InGaAlP or AlGaAs for example. GaN plugs allows AlInGaN device layer growth.

The active region can be formed embedded in the other layers, without exposing its edge to dangling bonds at the edge of the semiconductor body. Also, each plug gives rise to an isolated optoelectronic device, which can be controlled separately from other isolated optoelectronic devices grown on other plugs. This approach does not only provide a possibility to arrange a plurality of such recesses and plugs in rows and columns, but also avoid etching through the semiconductor required to electrically or optically isolate the individual u-LEDs.

The above-mentioned issue of NRR due to etching through the active region is thereby avoided.

In some aspects, the inventor proposes a method for processing an optoelectronic device. In some other aspects, the inventor proposes a plurality of optoelectronic devices. The following steps can therefore be applied for processing a single optoelectronic device, but also for processing a plurality of such optoelectronic devices.

In a first step, a Si substrate having a {100} surface-oriented plane is provided. The Si substrate also comprises a dielectric layer, for example, a SiO₂ layer on top of the {100} surface-oriented plane. For the purpose of the present application, if not otherwise noted, the top surface of the Si substrate is formed by the top surface of the dielectric layer deposited on the {100} surface-oriented plane. A plurality of separated recesses in rows and columns is provided in the surface of the Si substrate, whereas each recess of the plurality of recesses comprises a vertical hole through the dielectric layer and an {111} oriented sidewall at the bottom on at least two opposing sides.

In some aspects, a total depth of each recess, through the dielectric layer and equal to the thickness of the dielectric layer, is larger than a few multiples of the minimum width of the respective recess. In some other aspects, an inclination of the sidewalls is between 53° and 56° and in particular 54,7° with regards to the surface of the Si plane. The minimum aspect ratio (ratio of height of recess to width of recess) is given by the tangent of 54,7°=1.41, although higher aspect ratios are better to prevent dislocations that form later during growth in the recess.

Material of a plug is deposited in said plurality of separated recesses, in particularly up to the surface. Each plug comprises a III-V semiconductor material, for example GaN or GaAs. In some instances, the plug extends above the top surface of the Si substrate adjacent to the recess. In other words, growing a plug layer comprises depositing material of the plug into the recess and growing it vertically and laterally above the surface of the Si substrate surrounding the recess. The increased length and width may exceed several 100 nm. In some instances, the area of the plug adjacent to the recess covers an area more than about twice the area of the recess when viewed from top. In some other aspects, the material filled into the recess extends more than about 50 nm to 150 nm to each side of the respective recess.

A thickness of the material above the recess, i.e., the height of the plug, may range to a few hundred nm. The material of the recess is grown on the inclined sidewalls of the recess in the Si substrate and has very few defects such as dislocations and planar defects propagating out into the active region of a layer stack.

Further to the proposed method, a buffer layer or layers of III-V semiconductor material is deposited on each of the plugs. The buffer layer as well as the material of the plug may be doped to improve conductivity.

Buffer layers and plug layers may comprise the same or different materials.

Furthermore, the thickness of the buffer layers may vary and can be adjusted to the needs of the optoelectronic device. The buffer layer growth conditions can be adjusted to further thicken and widen the growth on top of the plug, and also optimized for growth of the active device layers grown subsequently. For example it can have dislocation trapping layers/dislocation filters, made up of multiple layers of different compositions of similar materials, which bend or absorb dislocations at their interfaces. In some instances, the buffer layers may be configured for further functionalities. In some instances, the buffer layers may comprise a DBR structure configured to reflect light from the subsequent optoelectronic device away from the plug. Such structures can of course also be included in some other layer; however the plug layer does need not comprise such functionality as it is used to bury defects and act as seed layer. The buffer layer may comprise a ternary or quaternary material like AlGaP, AlGaN, InGaP, InGaN, AlGaInP and AlGaInN.

In a next step, a plurality of layer stacks is formed on each of the buffer layers. Each layer stack may comprise an active layer in between two differently doped semiconductor layers. The active region may comprise a double heterostructure, a quantum well, a multi quantum well structure, quantum dots and the like. The growth of the respective layer stacks is performed in such way, that adjacent layer stacks are still separated by a space in between. Accordingly, the recesses in the Si substrate are arranged with a certain space in between to allow for separated growth of the layer stacks. A dielectric material is deposited on the sidewalls of each layer stack of the plurality of layer stacks, particularly by a conformal deposition method, such as ALD.

Finally, a contact area is formed on a top surface of each layer stack. The contact area comprises a transparent conductive material like TCO as the top surface of each layer stack may also act a light emission surface.

In some instances, the material of the buffer layer as well as the material of the layer stack is different from the material of the plug layer. For example each of the buffer layer and/or each of the layer stacks comprise a ternary or quaternary III-V semiconductor material in particular one of: InGaAIP, AlGaAs, InGaP, InGaN, AlGaN and InGaAIN. It is possible in some instances to choose different materials for a first set of layer stacks and a respective second set of layer stacks when depositing the III-V semiconductor material. In such a case, one set is covered by a temporary dielectric mask prior to depositing the material for the subsequent sets. Using different materials result in layer stacks configured to emit light of different wavelength. By proper selection of the ternary or quaternary materials, one can form RGB pixels on the surface of the Si substrate.

Some aspects concern the step of providing a plurality of separated recesses. For example, one may etch through the dielectric layer until the {100} surface-oriented plane of the Si carrier is exposed. This can be performed by a first etching process. In some instances, the recess comprises substantially perpendicular sidewalls, although it may occur that those sidewalls are slightly inclined. Once, the {100} surface-oriented plane of the Si carrier is reached, a second etching process is performed, etching into the {100} surface-oriented plane.

The first etching process can be different from the second etching process. For example, the second etching process may etch only the Si substrate, and not the dielectric material. The recess width in the Si can be made larger than in the dielectric, providing a way of blocking defects that are parallel to the {111} sidewalls of the Si recess.

The second etching process will result in inclined sidewalls, and a width particularly with an aspect ratio of (depth of recess in the dielectric which equals the thickness of dielectric)/(width of recess in the dielectric) being on the order of a few multiples of one, depending on the material system and growth conditions, and/or with a width of less than 200 nm. The minimum AR to prevent defects on {111} planes is about 1.41, but higher AR is better.

Consequently, the growth of the initial plug layers within the recess will be limited to those dimensions as well.

In some instances, growing a buffer layer of a III-V semiconductor material comprises the step of growing a DBR structure. The DBR structure may comprise a plurality of different ternary or quaternary materials having different refractive indices, such that light emitted by an active region of a layer stack is reflected back and away from the plug layers. The buffer structure may also comprise further functionality like adjustment of crystal structure, preventing dislocations or other defects from propagating into the layer stack and the like. The buffer structure may comprise a doped material, so it is configured for charge transport into the layer stack.

Due to the growth of the plug, the buffer layer may follow at least partially the imprinted growth direction. The buffer layer may comprise an inclined surface, also depending on the growth conditions and the material system. Likewise, the imprinted growth direction may continue into the layer stack. As a result, the step of growing a plurality of layer stacks comprises in some instances growing each layer stack at least partially with an inclined sidewall.

After depositing the layer stacks, a dielectric material is applied to the surfaces of the layer stacks. The dielectric material can comprise a transparent material like SiO₂ or Al₂O₃, deposited by a conformal process like atomic layer deposition, ALD. The dielectric material is deposited by ALD, wherein the material on the top surface is removed in a subsequent process. The thickness of the deposited dielectric material ranges from a few 10 nm to about 200 nm for example. In some instances, one may deposit a thin cladding layer of Al₂O₃ and a slightly thicker dielectric layer of a different material on top. The dielectric thickness can be optimized for high optical reflection, in combination with the subsequently deposited metal, and also to insulate the semiconductor from the current-carrying metal.

In some further instances, a reflective layer is subsequently deposited on the dielectric material and in particular along the sidewalls of the layer stack. The reflective material can be a conductive reflective metal. The reflective layer will reflect light not emitted through the main emission surface e.g. the top surface of the layer stack and thus improve the efficiency of the device. In addition, the material of the reflective layer may form supply lines for feeding current to the respective layer stack. The reflective material can be deposited by ALD or any other suitable conformal deposition process. The thickness of the reflective material may be greater than about 10 nm.

In some aspects, portions of the deposited dielectric material are removed from a top surface of each layer stack as to expose the top surface of each layer stack. This surface may form a contact area but also act as the main emission surface in some instances. Consequently a transparent conductive material is deposited on the exposed top surface. The transparent conductive material can be in electrical contact with the reflective conductive material.

After the layer stacks have been formed, the space in between adjacent layer stacks may be filled with a material to provide further stability. For example, in some instances, the space between adjacent layer stacks is filled with a dielectric material, for example, SiO₂ or TiOx. Alternatively, a conductive material, in particular a metal can be filled into the space. In some instances, a combination of both approaches is utilized thus filling some portions of the space with dielectric material and other portions with a metal.

The proposed principle provides a method for processing optoelectronic devices directly onto an SI carrier that may also include CMOS circuitry for controlling and supplying.

In some instances, however, the plurality of optoelectronic devices and layer stacks, respectively can be re-bonded from a growth substrate to the carrier. In some aspects, an index matched dielectric material is deposited in a space between the plurality of layer stacks after the layer stacks are grown. This step can be performed instead of applying a dielectric material on the sidewalls or actually corresponds to this step. The applied dielectric material in the space between the layer stacks may also extend above the top surface of the layer stacks. Hence, the dielectric material is planarized. In some instances, portions of the dielectric material are removed to expose the top surface of the layer stacks.

The structure is then re-bonded to an Si substrate, said substrate having electrical contact areas arranged in rows and columns and comprising circuitry connected thereto. The circuitry is usually implemented in CMOS technology, but any other technology like EEL, ECL or combinations thereof are suitable. The re-bonding process utilizes wafer to wafer hybrid bonding. After the re-bonding process, the growth substrate including the plug layer and optionally the buffer layer or portions thereof can be removed. In some instances, the inclined surface portion of the plug layer and/or the buffer layer are removed as well. As a result, the layer stack may comprise a small portion with an inclined surface but can also comprise a constant cross section.

In some further instances, a dielectric material is patterned and applied such that portions of the top surface of the rebonded layer stacks are exposed. The exposed portions of the layer stacks are covered by a conductive transparent material deposited thereupon. A metal grid may also optionally be formed on the patterned dielectric material adjacent to the layer stacks, wherein the metal grid is in electric contact with the conductive transparent material.

In some other aspects, a dielectric material is filled into spaces between the plurality of layer stacks after a dielectric material and a metal are deposited onto the sidewalls. Both of those dielectric materials can be different. The structure is then re-bonded to a temporary substrate carrier and the growth substrate including the plug layer is subsequently removed.

Contact portions are provided on the exposed surface of the buffer layer. Alternatively, portions of the buffer layer or the buffer layer itself can be removed as well such that the layer stack surface is exposed. The structure is then bonded with its contact portions to an Si substrate, said substrate having electrical contact areas arranged in rows and columns and comprising circuitry connected thereto. A wafer-to-wafer bonding process can be used. After rebonding, the temporary substrate carrier is removed.

In some instances, the step of filling the dielectric material into spaces is performed by a conformal deposition method for example, by Fast ALD or TEOS-ozone CVD without plasma. Such methods ensure that dielectric material is deposited even on surface areas not directly visible on top ensuring an even filling of the space.

Some other aspects concern the processing of devices that are configured for light emission of different wavelengths. In some instances, growing a plurality of layer stacks comprises depositing a first set of the plurality of layer stacks with a first III-V material system, a second first set of the plurality of layer stacks with a second III-V material system different from the first III-V material system and a third set of the plurality of layer stacks with a third III-V material system. The third III-V material system is different from the two previous ones or at least comprises a different composition of one of the previous material systems. For example, the three material systems are selected to provide R, G and B light emission. For emission of green and blue light the same basic material system can be used, for example AlInGaN, but with a different material composition in the metallic components. Alternatively three or even more sets of layer stacks can be deposited and processed differently.

In such instances, growing a plurality of layer stacks may further comprise depositing a first set of the plurality of layer stacks and a second first set of the plurality of layer stacks such that the first set of the plurality of layer stacks comprises inclined sidewalls extending from a bottom of the layer stack to its top and the second set of the plurality of layer stacks comprises sidewalls with at least a portion substantially perpendicular to a surface of the Si substrate. In such cases, the first set of the plurality of layer stacks may comprise a III-V material system that is different from a III-V material system of the second set of the plurality of layer stacks.

In some instances, the first and second sets of the plurality of layer stacks can be configured to emit light in the range between 400 nm and 600 nm that are in the blue and green regime. The third set of the plurality of layer stacks can be configured to emit light in the range between 600 nm and 700 nm in the red regime.

Some other aspects relate to an optoelectronic arrangement. The optoelectronic arrangement comprises an Si based substrate carrier having a plurality of contact areas connected to circuitry embedded in the Si substrate. A dielectric arranged on top of the Si based substrate carrier comprises a plurality of recesses arranged over the contact areas and filled with a conductive material. The optoelectronic arrangement further comprises a plurality of optoelectronic devices, said optoelectronic devices each comprising a layer stack having an active region and being in contact with the conductive material. A transparent and conductive contact layer contacts a surface of each layer stack of the plurality of optoelectronic devices, wherein said surface face away from the Si based substrate carrier. Furthermore, a first set of layer stacks of the plurality of optoelectronic devices comprises inclined sidewalls extending from a bottom of the layer stack adjacent to the Si based substrate carrier to its top. A second set of layer stacks of the plurality of optoelectronic devices comprises sidewalls with at least a portion generally perpendicular to a surface of the Si substrate carrier.

In some aspects thereof, at least one of the first and second set of layer stacks comprise a DBR structure arranged between the plug and the active region. The DBR structure is configured to reflect light form the active area of the respective layer stack towards a main emission surface. The main emission surface is a surface of the layer stack facing away from the substrate.

In some further aspects, sidewalls of each layer stack are covered with a dielectric material, wherein optionally a space between adjacent optoelectronic devices is at least partially filled with a reflective metal. Alternatively, a dielectric material, for example, SIO₂ or TiOx or a combination of dielectric and reflective is filled into the space.

In some instances, an inclined reflective material surrounds each of the layer stacks.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows; a first embodiment of an optoelectronic arrangement illustrating some aspects of the proposed principle;

FIG. 2 illustrates a second embodiment of an optoelectronic arrangement in accordance with some aspects of the proposed principle;

FIG. 3 shows a top view of an optoelectronic arrangement with some aspects of the proposed principle;

FIGS. 4A to 4D illustrate some aspects of a method for processing a plurality of optoelectronic devices in accordance with some aspects of the proposed principle;

FIGS. 5A to 5D show some further aspects of a method for processing a plurality of optoelectronic devices in accordance with some aspects of the proposed principle;

FIG. 6 shows a third embodiment of an optoelectronic arrangement illustrating some aspects of the proposed principle;

FIG. 7 illustrates a fourth embodiment of an optoelectronic arrangement illustrating some aspects of the proposed principle;

FIGS. 8A to 8D illustrate some details for different layer stacks in accordance with some aspects of the proposed principle; and

FIG. 9 shows a fifth embodiment of an optoelectronic arrangement illustrating some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It is understood that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

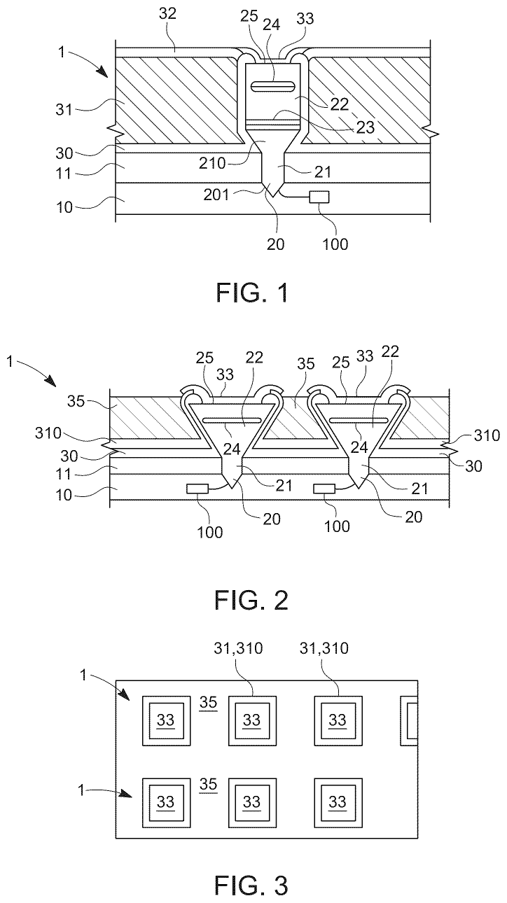

FIG. 1 illustrates an optoelectronic arrangement in accordance with the proposed principle. The optoelectronic arrangement 1 comprises an optoelectronic device which is grown on a substrate carrier based on silicon Si, utilizing aspect ratio trapping, ART to provide a largely defect reduced growth for the optoelectronic device. The optoelectronic arrangement 1 comprises a Si substrate 10, in which one or more CMOS circuitries 100 are implemented. In the present example, CMOS circuit 100 provides control and supplies signals to a conductive semiconductor material 20 deposited in a recess of the semiconductor substrate 10. The conductive material 20 forms the first plug layers upon which the rest of the plug 21 and 210 are grown, and then the optoelectronic device with its layer stack and active region is grown.

The recess comprises inclined surface walls 201 along {111} planes of the Si substrate. On the top of the {100} plane of the Si carrier substrate 10, a dielectric material 11 is deposited. For example, the dielectric material 11 comprises silicon dioxide SiO₂. The recess extends through the dielectric material 11 with vertical sidewalls. Thus, the recess has been etched in accordance with the proposed principle to obtain aspect ratio trapping, ART for the subsequent growth of the optoelectronic device, provided the height to width ratio of the recess in the dielectric is above a certain threshold. The recess is filled with a III-V semiconductor material forming part of the plug. Due to the initial growth on the {111} planes inside the recess, the vertical walls of the recess in the dielectric, and the aspect ratio of the recess (ratio of depth of recess in dielectric to width of recess in the dielectric), the plug layers 20 and 21 usually confine defects like dislocations, anti-phase boundaries and other planar defects: These defects are prevented from propagating into the layer stack above the level of the top of the recess.

The material of layer 21 extends above the surface of dielectric 11 and transposes into a wider section of the plug 210. On layer 210, buffer layers 23 which may comprise a DBR structure and further layers such as dislocation trapping layer TL or filter layers to prevent defects which propagate vertically up or which might arise during subsequent operation. Plug layers 210 also comprises an inclined surface extending from the top surface of dielectric layer 11 until a certain height. The layer stack 22 on top of buffer layer 23 then forms a general perpendicular surface with regards to the surface of the dielectric 11 on the {100} plane of substrate 10.

Layer stack 22 is grown on top of buffer layer 210 including an active region 24 and the two differently doped regions. The first one of those two differently doped regions is arranged between active region 24 and the buffer structure 23, while the second doped region is arranged between the main light emission surface 25 and the active region 24. For example, the first doped region can be n-doped, the second doped region may be p-doped, or vice versa.

Doping concentration may vary to improve carrier injection into the active region 24. The edges of the active regions do not reach the sidewalls. A thin material layer is arranged along the edges of active region 24, thereby burying it inside layer stack 22. While in the present figure, active region 24 extends till the respective edges, a person skilled in the art may recognize other implementations resulting in an active region embedded within and distances from the edges.

A dielectric material 30 is deposited on the sidewalls of the optoelectronic device and on the inclined sidewalls of plug 210 and the vertical surfaces of layer stack 22. The dielectric material 30 is transparent and deposited by an atomic layer deposition process to provide a smooth and even surface covering the surface of the layer stack 22. The transparent dielectric material 30 extends on the top surface of the dielectric material 11 and partially onto the top surface of layer stack forming the light emission surface 25. More particularly, dielectric material forms a surrounding edge enclosing the main emission surface 25. A conductive transparent material 33 like TCO is deposited on top of the light emission surface 25. It slightly extends on dielectric material 30 and contacts a metallic layer 31. This metal layer 31 is also deposited with a conformal deposition method such as, for example, ALD followed by plating, so that it covers the conformal dielectric 30 and forms part of a dielectric-metal mirror, and also conducts current to the TCO 33 from the subsequently deposited spreading metal 32. Metal 32 is also connected to the CMOS Si circuitry in the Si substrate through a via and plug (not shown).

A current is provided by circuitry 100 in operation of the proposed device and injected through the material of the plug layer 20 and buffer layer 21 and 210, respectively, into the layer stack 22. The second contact is formed by the transparent conductive material 33, thereby injecting charge carriers into the active region 24. In summary, the optoelectronic arrangement 1 implements an optoelectronic device based on a III-V semiconductor material directly grown on CMOS carrier substrate 10, which is already prepared for controlling and supplying the optoelectronic devices deposited thereupon. Any light generated in the active region 24 and emitted towards the buffer layer 21 is reflected by the DBR structure 23. Likewise, any light reflected to the side of the optoelectronic device will be reflected at metal layer 31.

FIG. 2 illustrates a further embodiment of an optoelectronic arrangement in accordance with the proposed principle. The optoelectronic arrangement 1 implemented in this embodiment comprises two optoelectronic devices grown on a common Si carrier substrate 10. As in the previous embodiment, the Si carrier substrate 10 includes power supply and control circuitry 100 implemented in CMOS technology. The circuitry 100 is in conductive connection with the material of plug layers 20 deposited on the {111} planes of recesses etched onto the plane of the Si substrate 10. The plug layers comprise also layers 21 through the dielectric layer 11. Plug layer 21 connects a respective layer stack 22, with buffer layers used as needed in-between, including DBR layers. Plug layers 20 acts as a seed layer to provide a preferred growth mode encapsulating growth and crystal defects within the recess of layers 10 and 11, respectively. The recesses themselves are arranged in rows and columns as to form separately addressable pixels of a micro-display.

Plug layer material 20 and 21 comprises a III-V semiconductor material like GaN, GaP or GaAs. This is a suitable material as other ternary and quaternary semiconductor materials based on the above can easily be grown on the plug. Also, II-VI materials such as ZnSSe can be grown on a GaAs plug. The grown layer stack 22 of the optoelectronic devices comprises an inclined sidewall. Layer stack 22 also includes an embedded active region 24 arranged between two differently doped regions, similar to the previous example. Also in this example, edges of the active region do not reach the sidewalls and the active region is embedded. One may recognize different growth variances to ensure embedding and spacing of the active region within the layer stack. A thin material layer is arranged along the edges of active region 24, thereby burying it inside layer stack 22.

The sidewalls of the optoelectronic devices as well as a surrounding edge portion of the main emission surface 25 is covered by a conformal deposition process, such as atomic layer deposition, of dielectric material 30. The dielectric material 30 is transparent and comprises, for example, SiO₂ in the present embodiment. A reflective metal layer 310 is arranged on top of the ALD dielectric material. The reflective metal layer 310 is also deposited with a conformal deposition process, such as ALD process, whereas portions of the reflective metal extend on the top surface and in particular on the top surface of the dielectric material 30. A transparent conductive material 33 is deposited on the main emission surface 25 and covers part of the reflective metal layer 310 thus forming an electrical contact with the reflective metal layer 310. As illustrated in the embodiment of FIG. 2, the metal layer 310 acts as an electric contact for the transparent conductive material 33 around and on each of the light emission surfaces, thereby providing the electric contact to the layer stack. The space between the optoelectronic devices is filled with a dielectric material 35. The metal layer 310 acts as a current spreading layer between a via/plug contact to the CMOS circuitry in the Si substrate and the conductive transparent material 33.

In operation charge carriers are injected via a circuitry 100 into the conductive material of plug layer 20. Likewise, charge carriers are injected through the conductive transparent material 33 into the top of the respective layer stacks.

The optoelectronic arrangement 1 in accordance with the proposed principles are formed in a processed Si carrier substrate, whereby the spaces between the respective recesses are adjusted in rows and columns such that the grown layer stacks are separated and spaced apart from each other. When viewed from top, the resulting structure resembles a display with respective subpixels or pixels arranged in rows and columns. Each of those pixels or subpixels is formed by an optoelectronic device grown from a recess in a Si carrier substrate including CMOS circuitry for controlling and supplying power to the devices. The devices are grown utilizing an aspect ratio trapping ART in the carrier substrate and in the recess in the dielectric to prevent defects from reaching into the active region of the layer stack.

FIG. 3 illustrates a top view of an example of such an optoelectronic arrangement. The optoelectronic arrangement comprises a plurality of optoelectronic devices arranged in rows and columns. Each of the optoelectronic devices comprise a transparent conductive material 33 arranged on the top emission surface and overlapping a reflective metal layer structure 310. The reflective metal surrounds the layer stack of the optoelectronic devices as for example illustrated in the embodiments of FIGS. 1 and 2. Light generated by the active region 24 inside the respective layer stacks and emitted towards a side will be reflected by the metal layer 31 or 310 towards the main emission surface. The layer stacks and optoelectronic devices are arranged such as to form a display with rows and columns of the respective pixels which can be controlled and adjusted separately. The space between the respective layer stacks is filled with a dielectric material or metal as shown in the previous embodiments.

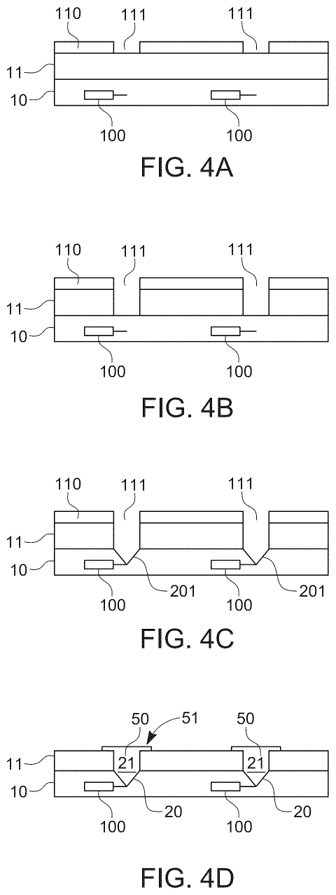

FIG. 4A) to 4E) illustrate various steps of processing an optoelectronic arrangement in accordance with the proposed principle. In FIG. 4A), a processed Si carrier substrate 10 is provided having a plurality of CMOS or other circuitry implemented therein. A portion of the circuitry includes a conductive layer or conductive wiring, which is arranged in portions of the Si carrier substrate 10 adjacent to recesses formed later for the deposition of the III-V semiconductor material. The Si carrier substrate 10 comprises a {100} plane forming the top surface, upon which a layer of dielectric material 11 is deposited. A photoresist layer 110 is deposited on top of dielectric material 11 and subsequently structured as to form openings 111 exposing portions of the top surface of the dielectric material 11. The locations of those openings 111 are directly above the conductive areas in carrier substrate 10 connected to the CMOS circuitry 100.

In a first etching step exposed portions of the dielectric material 11 are etched, as to form trenches which are limited both in X-and Y-directions. In other words, when viewed from top, the etched trenches each form a rectangle or another polygon defining a confined space.

This is ideally performed with a dry etch.

In a second etching step with a wet etchant, recesses are formed into the {100} surface of the carrier substrate 10 with the recess edges in the <110> directions. This etching causes an etch profile with inclined sidewalls along the {111} crystal planes of the Si substrate.

This is of particular benefit when growing a III-V semiconductor material as the growth forms a seamless continuation of the crystal structure without generating phase disorder and other defects. For example, monoatomic steps along {111} do not result in antiphase boundaries (APB). The limitation of the trench, both in X- and Y-direction provides an aspect ratio trapping ART with a defined cross-section versus the depth of the respective trench. This means that dislocations and planar defects can be trapped within the recess by the dielectric sidewalls.

After forming the respective trenches and recesses in the surface of the Si carrier substrate 10 as shown in FIG. 4C), the photoresist layer 110 surrounding the recesses is removed leaving an edge of dielectric material 11 exposed. Then, a plug layer material is deposited and grown inside the recesses in FIG. 4D). The material used for this purpose is a III-V semiconductor material, for instance GaN or GaAs. The material is doped to provide a good electrical connection to the conductive area surrounding the recess and to the respective CMOS circuitry 100.

The deposition of plug layer material continues until the recess through the dielectric material 11 is completely filled and is continued till a suitable height above the surface of the dielectric, which is optimized for the device with respect to shape, dimensions and defect density.

Due to the preferences during the deposition process and the respective set of the processing parameters, material 50 of plug layer is substantially initially deposited only inside the recesses and once growth continues above the recess, it can grow laterally. As visualized in FIG. 4D), the plug layer grown in the recess comprises substantially all the dislocations and defects, while the remaining material above the top surface forms a defect free layer. A buffer layer can be deposited on this layer to transition between the plug material and the device layers above. This buffer will also be of III-V material.

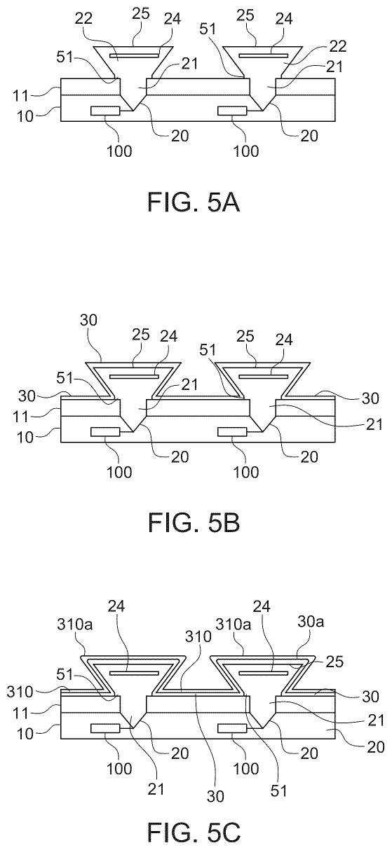

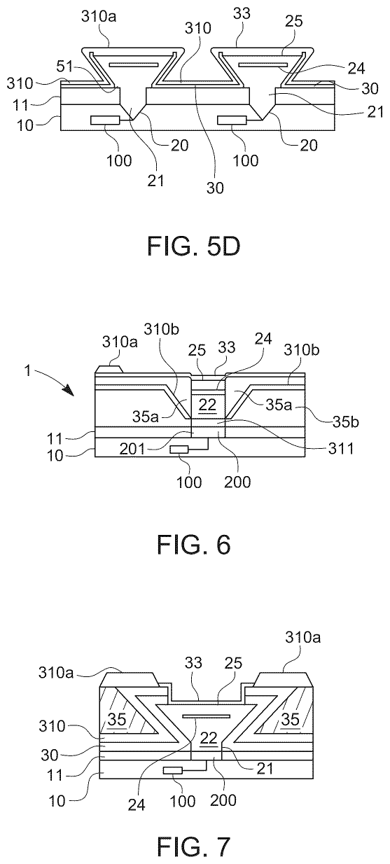

FIG. 5A illustrates the next step of processing an optoelectronic arrangement in accordance with some aspects of the proposed principle. Layer stacks 22 are deposited on the surface of the buffer layer.

Layer stack 22 includes differently doped layers starting from the plug material and buffer layer 21, respectively. In the present example, the layer stack comprises inclined sidewalls. Layer stack 22 further includes an embedded active region 24. Active region 24 is embedded in a layer stack 22 to the extent that it does not reach the respective outer side walls directly on the bottom doped layer of layer stack 22. The material of layer stack 22 is usually a ternary or quaternary semiconductor layer based on GaN, GaP or GaAs semiconductor material. Such a ternary and quaternary materials include GaAlP, GaAlN, InGaN, InGaP, InGaAlP and InGaAIN for example. It can also include II-VI materials such as ZnSSe.

The layer stack grown in FIG. 5A resembles a vertical lighting diode structure, on which the two electric contacts are formed on opposing sides. In the present example, one contact is given by the plug layers 20 21, while the other contact is defined by surface 25 on top of the layer stack 22 also forming the main emission side and facing away from the Si carrier substrate 10.

Layer stack 22 is deposited using chemical vapor deposition, physical vapor deposition or any other suitable growth method, which prefers growing the respective material on top of the plug material 51 already present. As a result thereof, the growth method may only deposit a small amount of material or no material on the dielectric layer 11. After growth of the respective layer stack illustrated in FIG. 5B, the dielectric layer 11 can be removed, leaving the top surface of the Si substrate 10 exposed (not done or shown in the figures).

Now illustrated in FIG. 5B, an atomic layer deposition or other conformal deposition step is performed to deposit a dielectric material 30 on the top surface of dielectric 11, as well as on the side and top surfaces of the respective optoelectronic devices and layer stacks 22, respectively. The atomic layer deposition process is a conformal deposition process, such that respective material is also deposited along the sidewalls of the respective layer stacks, which are not directly accessible to a non-conformal process, due to the shadowing effect of the inclined surfaces. Dielectric material 30 comprises SiO₂ or any other transparent insulating material.

A reflective conductive metal 310 is then deposited on top of dielectric material also using a conformal deposition method, such as ALD. Similar to the results of the previous dielectric process steps, the reflective material 310 covers the dielectric material on the sidewalls of the respective optoelectronic devices and also extends between the spaces of two adjacent optoelectronic devices as well as on the respective top surface, thereupon forming layer 310a.

The reflective metal layer 310 comprises two functionalities. Those include charge carrier transport to the subsequently deposited transparent conductive oxide, for electrically connecting a contact of the respective optoelectronic devices. The other main functionality is based on the reflectivity of the deposited metal, namely, to reflect light from the active region 24 towards the main emission surface 25 when the devices are operated. The resulting structure is depicted on FIG. 5c.

In a subsequent step, a photoresist layer can be coated onto the wafer, patterned to expose the top of the reflective metal 310a. Etching can be performed, which removes the top portions 30a of dielectric material 30 as well as 310a of the reflective metal. In other words, this step now exposes the top surface of the optoelectronic devices also forming the respective contact area. A patterned transparent conductive oxide 33 is now deposited on that exposed top surface. The conductive oxide covers portion of the reflective metal layer 310 thereby forming an electrical contact with the reflective metal layer 310 as illustrated in FIG. 5D). In operation of the devices reflective metal 310 is used as a common charge carrier transport layer to inject charge carriers through the TCO 33 through the main emission surface into the active regions 24 of the optoelectronic devices. Thicker metal can be plated in-between the pixels to further help the current spreading as well as to provide more stability to the individual pixels.

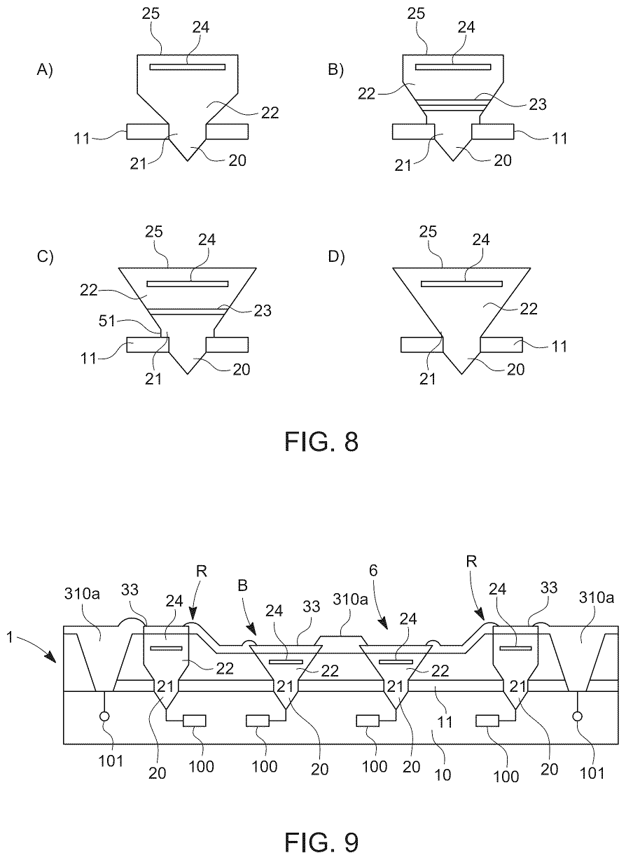

In the present examples, the growth of the respective layer stack is to some extent depending on the material of the plug layers 20 and 21. FIGS. 8A to 8D illustrate various growth options for the respective layers including the layer stack 20, in which active regions 24 are embedded in the respective layer stack.

For example as illustrated in FIG. 8A), the growth direction changes from an inclined angle to a substantially perpendicular angle with regards to the surface of the dielectric material 11. However, as illustrated, the increase in the cross section along the buffer layer will not exceed a maximum of a few hundred nanometers. This is beneficial when implementing u-LEDs on an Si carrier with a high density using the aspect ratio trapping (ART) approach as proposed by the present application.

FIG. 8B illustrates a similar example, whereas material of the plug layer 21 grows to a certain extent laterally on the top surface of dielectric material 11 adjacent to the recess. A subsequent growth of the buffer layer follows an inclined surface angle. In addition in this particular example, a buffer material including a DBR structure 23 is deposited on the plug layer material 21. DBR structure 23 comprises a plurality of binary, ternary or quaternary layers with different material of a dedicated thickness, such that the light emitted from active region 24 towards the DBR structure 23 is reflected back towards the main emission surface 25. In addition to this functionality, the buffer structure can also be used as trapping layers to prevent potential defects from expanding into the layer stack 22 and active region 24.

FIG. 8C illustrates a further example, in which the inclined surface extends throughout the layer stack 22 from the bottom of material 51 adjacent to dielectric material 11 to the top emission surface 25. It is possible in this regard to provide trapping layers or DBR structures 23 as indicated inside layer stack 22. Material 51 of plug layer 21 has also laterally grown on the top surface of dielectric material 11.

FIG. 8D finally illustrates an example, in which the layer stack 22 grows from the plug layer 21 inside the recess of dielectric material. The layer stack 22 with inclined sidewalls therefore extends from the top surface of dielectric material 11, thereby forming a truncated pyramid like structure, whose X-and Y-dimensions are defined by the height of the layer stack 22.

FIG. 6 illustrates a different example of an optoelectronic arrangement. In this embodiment, the optoelectronic devices are grown on a separate Si carrier substrate and are subsequently re-bonded to the final SI carrier. Such an approach can utilize wafer-to-wafer bonding. Particularly in cases in which process parameter for growing the optoelectronic devices may damage circuitry inside the Si carrier substrate, growth of the optoelectronic devices on a temporary growth substrate with a subsequent bonding process is necessary.

The optoelectronic arrangement 1 comprises an Si carrier substrate 10 with a patterned dielectric layer 11 arranged on top. A plurality of recesses arranged in rows and columns is located in the dielectric material accessing contact areas on the surface of the Si carrier substrate. Each of the recesses is filled with a conductive material, such as a metal, such that an even surface with the dielectric material 11 is formed. This surface can be finished by polishing to get a flat surface suitable for direct bonding. The Si carrier substrate 10 with the patterned dielectric layer is processed separately.

The layer structure with the optoelectronic device is bonded to the Si carrier substrate using, for example, hybrid direct bonding, to achieve a connection between planarized dielectric portions 35b and the surface of the dielectric 11 and between the conductive material 200 inside the recess of the dielectric 11 and a conductive metal layer portion 311. The layer structure comprises an optoelectronic layer stack 22 with substantially perpendicular sidewalls arranged with one of its contact layers on metal contact layer 311. A TCO can be arranged in between the semiconductor contact layer and the metal contact layer if needed. Said portion forms one contact of the layer stack 22. The layer stack comprises an active region 24 and the second contact layer forming a light emission surface 25 arranged opposite metal contact layer 311 and covered by a transparent conductive metal layer 33 like TCO.

The layer stack 22 is arranged in a recess with inclined sidewalls. that are covered by conductive and reflective metal layer 310b. Similar to the previous embodiments, the metal layer 310b is isolated from bottom portion 311 and provides only the optical functionality of reflecting light from the active region towards the main emission surface 25 but no further electrical function. The space between the layer stack 22 and the reflective metal layer 310b is filled with a transparent and index matched dielectric material 35a. Said material 35a covers the sidewalls completely and also extends above the space and covers any portion of layer 310b arranged on top of the planarized dielectric 35b. Consequently, active region 24 lies within the larger trench whose sidewalls are covered by the reflective layer 310b. This will improve the reflexion of light emitted by the active region towards the side or in direction of the n-doped region. The transparent conductive material 33 contacting the top portion of layer stack 22 is arranged on the index matched dielectric and contacts a metal grid structure 310a. There is a dielectric separation between the bottom metal contact pad 311 and the reflector metal on the angled sidewalls of the pixel 310b, which makes the bottom contact of each pixel individually addressable. The top contact made by the combination of TCO 33 and the metal grid 310a is the common contact for all the pixels.

The optoelectronic arrangement according to FIG. 6 is processed by a method sharing some steps of the previously shown processing method. Any processing and preparation of the Si carrier substrate is similar.

For preparation of the optoelectronic devices, a temporary Si growth substrate is provided with its top surface being the {100} plane. The SiO₂ dielectric material is deposited thereupon, and trenches are etched accordingly. The position and size of the trenches should resemble the contact areas on the carrier substrate. Then, the plug layer, buffer layer and layer stack are grown in accordance with the proposed principle. These steps are similar or equal to the process steps illustrated in FIGS. 4A) to 4E) and 5A).

After growth of the layer stack an index matched dielectric 35a is applied using a conformal deposition method. For example, TiOx can be used for emitters based on the GaN material. The dielectric material is polished to provide a planarized surface. A patterned photoresist is then applied on the top surface of the dielectric layer and the top surface of the layer stack. The dielectric material 35a is etched to form inclined sidewalls between the respective layer stacks. The angle of the sidewalls is optimized for light extraction and directionality as needed. Furthermore, contact areas are opened on the top surface of the layer stack. A patterned TCO and a patterned reflective metal are then applied suitable for hybrid bonding at a later step. The metallic reflective layer extends on the sidewalls forming layer 310b. After this step, the reflective metal is covered by a planarizing dielectric 35b, that is planarized to open the metal layer 311 forming the contacts for the layer stack and provide an even surface.

The structure is then bonded to the Si carrier substrate 10 using a hybrid bonding method. This step forms the individually addressable contacts to the array. Following the re-bonding step the Si growth substrate can be removed until the layer stack's second contact layer is reached. If needed an insulating patterned dielectric is applied to ensure that any short circuit between layer 310b and a transparent conductive layer contacting the second contact area is prevented. This dielectric can also act as part of an antireflection coating, along with the TCO 33. The transparent conductive layer 33 covers the main emission area 25 of each layer stack and acts as a common contact or current spreader connected to a metal grid structure 310a. The spreader metal can be connected to the CMOS wafer either with a via or a wire bond (common 2nd contact).

FIG. 7 illustrates a further example of an optoelectronic arrangement in accordance with some aspects of the proposed principle. The sidewalls of layer stack 22 are inclined. A doped region forming the bottom contact is followed by an active region 24 and a doped region of the opposite doping type. The top surface of the top doped region forms the main emission surface 25.

The sidewalls of the layer stack 22 and the buffer layer 21 are covered by a transparent dielectric 30 that is deposited by a conformal process such as ALD. A reflective metal 310 covers the dielectric layer 30, also deposited by a conformal deposition process such as ALD. The dielectric extends along the sidewalls and surrounds the top edge portion of the layer stack adjacent to the main emission surface. Likewise, the reflective layer 310 covers the dielectric and thereby forms an electrical contact with a transparent conductive material 33 on top of the main emission surface. The conductive layer 33 and the reflective layer 310 can also be in contact with a metal grid structure 310a arranged on the top surface between two adjacent layer stacks. The space between layer stacks and the dielectric and metal layer deposited thereupon is filled with a material 35, which can be a dielectric or a polymer. In any case metal grid structure 310a and 310 form a common contact.

Processing an optoelectronic arrangement as illustrate in FIG. 7 is done using similar process steps as shown in the previous embodiments. A plurality of layer stacks is grown on a temporary Si growth substrate using the proposed principle also shown in FIGS. 4A) to 4E) and 5A) to 5B) for example. After processing the layer stack, a dielectric material 30 using a conformal deposition method such as ALD to isolate each pixel and also to act as part of a reflector is applied. Then, a metal layer also with a conformal deposition method such as ALD is applied to act as the metal part of the reflector, and also to conduct current to the thicker metal spreader. Those two method steps are similar to the ones illustrated in FIGS. 5C) and 5D), respectively.

In a next step a thick conformal dielectric material 35 is deposited to fill the spaces between the various layer stacks. For this purpose, one may use a conformal deposition method like for example fast ALD or TEOS-ozone CVD (no plasma). A polymer such as BCB can also be used, with dielectric on top for direct bonding later. The deposited dielectric is planarized and the structure subsequently bonded another temporary carrier. The carrier can be an Si carrier with a SiO₂ layer on top or another type of substrate. The growth substrate is removed, for example by grinding and polishing till the contact portions of the layer stack is reached. In the present example this is a part of the contact layer facing the dielectric 11 in FIG. 7. Other patterned layers such as metal and dielectrics are applied until the structure for the wafer bonding to a CMOS wafer is possible.

The structure is then bonded to the CMOS Si carrier substrate using hybrid bonding. The temporary substrate is removed by grinding and polishing till the metal layer is reached.

The second contact on top of the layer stack is opened and a patterned transparent conductive material like a transparent conductive oxide is applied. A thick spreader metal can be deposited as a grid 310a and connected to the Si carrier substrate either with a via or a wire bond. This will act as the common 2nd contact.

The implementation of optoelectronic devices processed by an aspect ratio trapping triggered by an Si carrier substrate enables the utilization of the different materials for the growth of the respective optoelectronic devices. As a result thereof, optoelectronic devices of different light emissions for example red, green, or blue can be a processed on a single Si wafer and particular on an Si functional semiconductor substrate area.

An example for such optoelectronic arrangement is presented in FIG. 9. The optoelectronic arrangement 1 comprises a plurality of optoelectronic devices, which are configured in operation to emit light of different wavelengths. In particular, the optoelectronic arrangement illustrates two optoelectronic devices R configured to emit red light as well as one optoelectronic device B and G configured to emit blue light and green light, respectively. The material used for processing the optoelectronic devices and the respective layer stacks for the devices configured to emit red light is different from the material for processing the devices configured to blue light and green light, respectively. This is illustrated by the different height as well as a slightly different shape of the respective optoelectronic devices. In the present example, the optoelectronic devices R configured to emit red light comprise a layer stack having substantially perpendicular sidewalls with regard to the surface of the dielectric material 11, while the layer stack 22 of the optoelectronic devices B and G, that is for blue and green light, are shaped differently with an inclined surface extending from the top of dielectric material 11 to the main emission surface 25. This is shown as such only as an example, the exact shapes and dimensions depend on the materials and growth conditions.

Each optoelectronic device is formed with an aspect ratio trapping including plug layers 20 and 21, which includes highly conductive material connected to a respective CMOS circuitry 100 within the Si carrier substrate 10. The top emission surfaces also forming the other contact of the respective optoelectronic devices are covered by a transparent conductive layer 33. This layer forms a common layer with a respective metal grid structure 310a in between.

Metal structure 310a also extends through the dielectric material 11 at some locations and contacts a supply node 101 in the Si carrier substrate 10.

The proposed principle of an aspect ratio trapping using a III-V semiconductor material deposited in a recess within a Si substrate provides a solution for direct processing of optoelectronic devices on an Si substrate for later use. This will not only provide possibility to prepare an Si wafer with several supply and control circuitry separately from the optoelectronic devices (see FIGS. 1 and 2 as well as 9) but also implements an easier solution for wafer to wafer bonding as illustrated in the embodiments of FIGS. 6 and 7. The aspect ratio trapping ensures a restriction both in X and Y direction thus enabling growth initiating on {111} Si planes with dislocations and planar defects being trapped within the recess formed in the Si substrate and in the dielectric material deposited on top thereof. In any case, and in contrast to conventional methods the lattice mismatch between the Si material and with the III-V semiconductor material can be compensated using the proposed growth method. Growth initiated on {111} Si also prevents anti phase boundaries in the III-V material.

1-26. (canceled)

27. A method for processing an optoelectronic device, the method comprising:
providing a Si substrate having a {100} surface-oriented plane and having a dielectric layer arranged thereupon;
providing a recess on the surface of the dielectric layer and extending into the Si substrate, whereas the recess comprises a {111} oriented sidewall on at least two opposing sides in the Si substrate;
growing a plug layer in the recess, wherein the plug layer comprises a III-V semiconductor material up to and above the surface of the dielectric layer;
growing a buffer layer of a III-V semiconductor material on the plug layer, the plug or buffer layer being at least partially grown with an inclined sidewall having an increasing cross-section with increasing distance from the dielectric layer;
growing a layer stack on the buffer layer, the layer stack comprising an embedded active layer and being separated from each other, wherein the embedded active layer is spatially distant from sidewalls of the layer stack;
applying a dielectric material on the sidewalls of the layer stack; and
applying a contact area on a top surface of the layer stack.

28. The method according to claim 27, wherein a depth of each recess in the dielectric layer is larger than 1.41 times a width of the respective recess.

29. The method according to claim 27, wherein each of the plug layers comprises one of GaN and GaAs and each of the buffer layers and/or each of the layer stacks comprises InGaAlP, AlGaAs, InGaP, InGaN, AlGaN, InGaAlN or ZnSSe.

30. The method according to claim 27, wherein providing the Si substrate comprises providing a Si substrate with an SiO₂ layer on top of the {100} surface-oriented plane.

31. The method according to claim 27, wherein growing the buffer layer of the III-V semiconductor material comprises growing a DBR structure.

32. The method according to claim 27, wherein growing the buffer layer of the III-V semiconductor material comprises growing a dislocation filter layer within the buffer layer.

33. The method according to claim 27, further comprising depositing a reflective conductive material on the dielectric material.

34. The method according to claim 27, wherein filling the dielectric material into spaces is performed by a conformal deposition method comprising a Fast ALD or a TEOS-ozone CVD without plasma.

35. A method for processing a plurality of optoelectronic devices, the method comprising:
providing a Si substrate having a {100} surface-oriented plane having a dielectric layer arranged thereupon;
providing a plurality of separated recesses in rows and columns on the surface of the dielectric layer and extending into the Si substrate, whereas each recess of the plurality of recesses comprises a {111} oriented sidewall on at least two opposing sides in the Si substrate;
growing a plug layer in the plurality of separated recesses, each of the plug layer comprises a III-V semiconductor material up to and above the surface of the dielectric layer;
growing a buffer layer of a III-V semiconductor material on each of the plug layers, each of the plug or buffer layers being at least partially grown with an inclined sidewall having an increasing cross-section with increasing distance from the dielectric layer;
growing a plurality of layer stacks on each of the buffer layers, each of the layer stacks comprising an embedded active layer and being separated from each other, wherein the embedded active layer is spatially distant from sidewalls of the layer stacks;
applying a dielectric material on the sidewalls of each layer stack of the plurality of layer stacks; and
applying a contact area on a top surface of each layer stack.

36. The method according to claim 35, wherein growing the plug layer comprises depositing a material of the plug layer into the recess and onto a surface area of the Si substrate surrounding the recess.

37. The method according to claim 35, wherein providing the plurality of separated recesses comprises:
etching through the dielectric layer until the {100} surface-oriented plane is exposed, wherein an aspect ratio of depth of recess in the dielectric layer to a width of the recess in the dielectric layer is larger than 1.41 and/or with a width of less than 200 nm, and etching into the {100} surface-oriented plane, wherein the etching process results in inclined sidewalls.

38. The method according to claim 35, wherein growing the plurality of layer stacks comprises growing each layer stack at least partially with an inclined sidewall.

39. The method according to claim 35, wherein applying the dielectric material on the sidewalls of each layer stack comprises performing an atomic layer deposition of the dielectric material.

40. The method according to claim 35, further comprising:
removing portions of the dielectric material on a top surface of each layer stack to expose the top surface of each layer stack; and
depositing a transparent conductive material on the exposed top surface such that the conductive material is in electrical contact with a reflective conductive material.

41. The method according to claim 35, further comprising:
filling a space between adjacent layer stacks with at least one of:
a dielectric material comprising SiO₂ or TiOx; or a conductive material comprising a metal.

42. The method according to claim 35, further comprising, after growing the plurality of layer stacks:
depositing an index matched dielectric in a space between the plurality of layer stacks;
planarizing the dielectric and optionally removing portions thereof to expose a top surface;
etching the index matched dielectric to form sidewalls at defined angles;
re-bonding to an Si substrate, the Si substrate having electrical contact areas arranged in rows and columns and comprising circuitry connected thereto; and
removing a growth substrate including the plug layer and optionally the buffer layer or portions thereof comprising the inclined surface.

43. The method according to claim 42, further comprising:
applying a patterned dielectric such that portions of the top surface of re-bonded layer stacks are exposed;
applying a conductive transparent material on the exposed portions; and
optionally forming a metal grid on the patterned dielectric adjacent to the layer stacks, wherein the metal grid is in electric contact with the conductive transparent material.

44. The method according to claim 35, further comprising, after the step of applying a dielectric material:
filling a dielectric material into spaces between the plurality of layer stacks;
re-bonding to a temporary substrate carrier;
removing a growth substrate including the plug layer;
providing contact portions on the exposed surface of the buffer layer;
bonding to a Si substrate, the Si substrate having electrical contact areas arranged in rows and columns and comprising circuitry connected thereto; and
removing the temporary substrate carrier.

45. The method according to claim 35, wherein growing the plurality of layer stacks comprises depositing a first set of the plurality of layer stacks with a first III-V material system, a second set of the plurality of layer stacks with a second III-V material system different from the first III-V material system and a third set of the plurality of layer stacks with a third III-V material system different from the first and second material systems.

46. The method according to claim 35, wherein growing the plurality of layer stacks comprises depositing a first set of the plurality of layer stacks, a second set of the plurality of layer stacks and a third set of the plurality of layer stacks such that the first and second sets of the plurality of layer stacks comprises inclined sidewalls extending from a bottom of the layer stack to its top and the third set of the plurality of layer stacks comprises sidewalls with at least a portion substantially perpendicular to a surface of the Si substrate.

47. The method according to claim 46, wherein the first set and the second set of the plurality of layer stacks is configured to emit light in a range between 400 nm and 600 nm, inclusive; and wherein the third set of the plurality of layer stacks is configured to emit light in the range between 600 nm and 700 nm, inclusive.

48. An optoelectronic device comprising:
a Si based substrate carrier having a contact area connected to circuitry embedded in the Si substrate;
a dielectric located on top of the Si based substrate carrier having a recess arranged over the contact area and filled with a conductive material;
an optoelectronic component comprising a layer stack having an active region and being in contact with the conductive material, wherein the active region is spatially distant from sidewalls of the stack layer; and
a transparent electric contact layer contacting a surface of the layer stack of the optoelectronic component, the surface facing away from the Si based substrate carrier, wherein the layer stack of the optoelectronic component comprises one of:
inclined sidewalls extending from a bottom of the layer stack adjacent to the Si based substrate carrier to its top, and sidewalls with at least a portion substantially perpendicular to a surface of the Si substrate carrier.

49. An optoelectronic arrangement comprising:
a Si based substrate carrier having a plurality of contact areas connected to circuitry embedded in the Si substrate;
a dielectric on top of the Si based substrate carrier having a plurality of recesses arranged over the contact areas and filled with a conductive material;
a plurality of optoelectronic devices, the optoelectronic devices comprising a layer stack having an active region and being in contact with the conductive material, wherein the active region is spatially distant from sidewalls of the stack layer; and
a transparent electric contact layer contacting a surface of each layer stack of the plurality of optoelectronic devices, the surface facing away from the Si based substrate carrier, wherein a first set of layer stacks of the plurality of optoelectronic devices comprises inclined sidewalls extending from a bottom of the layer stack adjacent to the Si based substrate carrier to its top, and
wherein a second set of layer stacks of the plurality of optoelectronic devices comprises sidewalls with at least a portion substantially perpendicular to a surface of the Si substrate carrier.

50. The optoelectronic arrangement according to claim 49, wherein at least one of the first and second set of layer stacks comprise a DBR structure arranged between the Si substrate and the active region.

51. The optoelectronic device or arrangement according to claim 49,
wherein sidewalls of each layer stack are covered with a dielectric material, and
wherein optionally a space between adjacent optoelectronic devices is at least partially filled with one of:
a reflective metal, or
a dielectric material comprising SIO₂ or TiOx.

52. The optoelectronic device or arrangement according to claim 48, further comprising:
an inclined reflective material surrounding the layer stack.
